(19) United States
(12) Patent Application Publication
(10) Pub. No.: US 2004/0111871 A1
(43) Pub. Date: Jun. 17, 2004

(54) Method for adjusting spacings in magnetic circuits

(76) Inventors: Christian Braeuer, Steyr (AT); Stefan Holl, Ottnang (AT)

Correspondence Address: RONALD E. GREIGG, GREIGG & GREIGG P.L.L.C., Suite One, 1423 Powhatan Street, Alexandria, VA, 22314, US

(21) Appl. No.: 10/728,833

(22) Filed: Dec. 8, 2003

(30) Foreign Application Priority Data
Dec. 9, 2002 (DE) 1 02 57 380.8

(51) Int. Cl. H01H 1/00; G01R 1/00

(52) U.S. Cl. 29/602.1; 29/593

(57) ABSTRACT

A method is disclosed for adjusting a spacing within a magnetic circuit, in particular the spacing between a magnet armature and a magnet core, in which the magnet armature has an armature plate and an armature bolt which are joined together in a relative position, characterized in that after the mounting of the magnet armature comprising the armature plate and armature bolt, the relative position between the armature plate and the armature bolt is adjusted, in the context of a pressing operation, to a first defined size or a second defined size.

### BACKGROUND OF THE INVENTION

1. Field of the Invention

For actuating fuel injectors in injection systems of internal combustion engines, not only mechanical-hydraulic boosters and piezoelectric actuators, but often magnet valves are used. Closing elements for relieving a control chamber, which is at high pressure and is acted upon by a control volume, are moved by means of actuators embodied as magnet valves. By means of the pressure relief of and imposition of pressure on the control chamber, a reciprocating motion of the injection valve member inside the fuel injector is effected.

2. Description of the Prior Art

German Patent Disclosure DE 196 50 865 A1 has as its subject a magnet valve for controlling the fuel pressure in the control pressure chamber of an injection valve, for instance of a common rail injection system. By way of the fuel pressure in the control pressure chamber, the motion of a valve piston is also controlled, with which piston an injection opening of the injection valve is opened or closed. The magnet valve has an electromagnet, disposed in a housing part; a movable armature; and a control valve member, moved by the armature and urged in the closing direction by a closing spring, which control valve member cooperates with a valve seat of the magnet valve and thus controls the outflow of fuel from the control pressure chamber. From German Patent Disclosure DE 197 08 104 A1 as well, a magnet valve of this kind for controlling the fuel pressure in the control pressure chamber of an injection valve is known.

To avoid the disadvantageous consequences of armature recoil, occurring in magnet valves after they have been triggered, the armatures of the magnet valves disclosed in DE 196 50 865 A1 and DE 197 08 104 A1 are embodied as two-part magnet armatures. The armatures include an armature bolt and an armature plate received slidably-displaceably on the armature bolt. Using two-piece armatures reduces their effectively braked mass and thus the kinetic energy that causes the armature to recoil as it strikes the valve seat. Triggering of the magnet valve does not lead to a defined injection quantity again until the armature plate is no longer continuing to swivel. Provisions are therefore required for reducing the continued bouncing or swiveling of the armature plate. Such provisions are required especially whenever brief time intervals between a preinjection and a main injection phase are required. For solving this problem, damping devices are used, which include one fixed part and one part that is moved along with the armature plate. The fixed part can be formed by an overstroke stop, which limits the maximum travel length by which the armature plate can be displaced on the armature bolt. The moving part is formed by a protrusion on an armature plate, the protrusion being oriented toward the fixed part. The overstroke part can be formed by the face end of a sliding block, which guides the armature bolt and is fastened in fixed fashion in the housing of the magnet valve, or by a part disposed upstream of the sliding block, such as an annular disk. When the armature plate approaches the overstroke stop, a hydraulic damping chamber is created between the face ends, facing one another, of the armature plate and the overstroke stop. The fuel contained in the hydraulic damping chamber generates a force that counteracts the motion of the armature plate, so that the continued swiveling of the armature plate is severely damped.

A problematic feature of the magnet valves of DE 196 50 865 A1 and DE 197 08 104 A1 is the precise adjustment of the maximum sliding travel that is meant to be available to the armature plate on the armature bolt. The maximum sliding travel, also known as an overstroke, is adjusted by means of replacing the overstroke disk, additional spacer disks, or grinding down the overstroke stop. Since these provisions require an iterative adjustment to be performed in increments, they are very complicated and can be automated only with difficulty and therefore lengthen the production cycle times not inconsiderably.

German Patent Disclosure DE 101 00 422.2 has as its subject a magnet valve for controlling an injection valve of an internal combustion engine. The magnet valve includes a movable armature with an armature plate and an armature bolt, and a control valve part, moved with the armature and cooperating with a valve seat, for opening and closing a fuel outlet conduit of a control pressure chamber in the injection valve. The armature plate is supported slidingly displaceably, under the influence of its inertial mass, in the closing direction of the control valve member on the armature bolt, counter to the tensing force of a restoring spring acting on the armature plate. By means of a hydraulic damping device, the continued swiveling of the armature plate upon aerodynamic displacement on the armature bolt can be damped. The damping device includes one fixed part and one part moved with the armature plate. The part moved with the armature plate is formed by a final control element, which is disposed on a portion of the armature plate remote from the electromagnet and which is displaceable for adjusting the maximum sliding travel of the armature plate relative to a face end, toward the electromagnet, of the armature plate in the sliding direction of the armature plate. The final control element is embodied as a screw member with a female thread; it comprises a portion of the armature plate that is penetrated by the armature bolt and is screwed to a portion of the armature plate that is provided with a male thread.

### OBJECT AND SUMMARY OF THE INVENTION

With the provision proposed according to the invention, extremely accurate spacings, in the micrometer range, can be generated. To that end, a preassembled magnet armature assembly, which includes an armature plate and an armature bolt, is placed in a pressing tool. In the pressing tool, by pressing inward or outward afterwards, the relative position between the armature plate and the armature bolt of the magnet armature assembly can be adjusted. To that end, extremely accurately calibrated shims or spacers are used, but after the adjusting operation, that is, the adjusting of a defined size that defines the relative position between the armature plate and the armature bolt, they are removed again. The relative position between the armature bolt and armature plate prevailing in the preassembled magnet armature assembly before the placement in the pressing tool is recalibrated with extreme accuracy and set to a set-point relative position. The magnet armature assembly recalibrated in this way can be used within a magnet valve component group with which fuel injectors of fuel injection systems can be triggered. As a result, in fuel injectors that are actuated via a magnet valve, graduated adjusting rings or postmachining processes employed previously can be avoided. In large-scale mass-produced fuel injectors for fuel injection systems for internal combustion engines, the avoidance of adjusting disks or other adjusting elements represents a major cost saving.

Until now, in assembling fuel injectors, compensation disks were used, which are available in the form of graduated adjusting disks and remain in the fuel injector after the assembly of the fuel injector. Depending on the production quality of the magnet armature supplied with the magnet valve component group, the compensation disks were assembled and disassembled in accordance with the required tolerances of the remanent air gap between the armature plate and the face end of the magnet coil, until the requisite remanent air gap was established. This lengthens the assembly time of fuel injectors not inconsiderably, and professional experience plays a not inconsiderable role in terms of the quality of the assembled fuel injectors. Assembly of the fuel injectors by persons who are not highly skilled is a major source of error.

With the provisions proposed by the invention, it can also be attained that greater tolerances in the production of the components of the magnet armature can be allowed, but these are not significant when the relative position of the armature bolt to the armature plate of the magnet armature is being pressed in a pressing tool.

### BRIEF DESCRIPTION OF THE DRAWING

The invention will be better understood and further objects and advantages thereof will become more apparent from the ensuing detailed description of preferred embodiments taken in conjunction with the drawings, in which:

FIG. 1 shows a preassembled magnet armature assembly along with a magnet core and both defined sizes and size involving tolerances; and

FIG. 2 shows the schematic layout of a pressing device for pressing a magnet armature assembly to a defined size.

### DESCRIPTION OF THE PREFERRED EMBODIMENTS

In the drawing, a magnet armature assembly 1 is shown in which the magnet armature 1 includes an armature plate 2, which has a first, upward-pointing face end 3 and a second, downward-pointing face end 4. The armature plate 2 furthermore has an armature plate bore 5. The magnet armature 1 further includes an armature bolt 7, which penetrates the armature plate bore 5 in the armature plate 2. The armature plate 2 and the armature bolt 7 are joined one inside the other via a press fit 6.

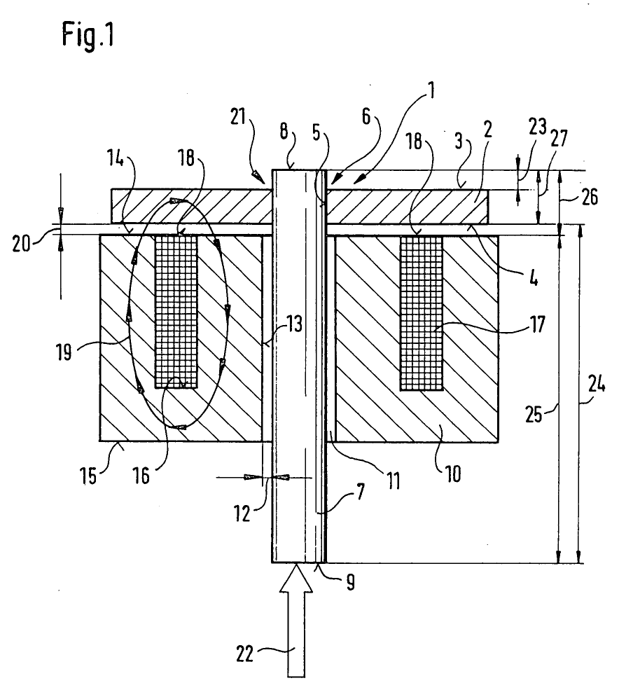

A first face end 8 of the armature bolt protrudes by a size involving tolerance 23 with respect to the first face end 3 of the armature plate 2. Between the second face end 4 of the armature plate 2 and a second face end 9 of the armature bolt, a first defined size 24 is set with extreme accuracy. A second size involving tolerance 26 designates the spacing between the first face end 8 of the armature bolt and the first face end 14, pointing toward the armature plate 2, of the magnet core 10 and is predetermined individually by the structural part. An essential functional feature for the magnet armature assembly 1 shown in FIG. 1 is the remanent air gap 20 (h), which is established between the second face end 4 of the armature plate 2 and the first face end 14 of the magnet core 10. The remanent air gap 20 should be set to micrometer accuracy. Because of production factors, a size involving tolerance 25 results between the second face end 9 of the armature bolt and the face end 14 of the magnet core 10.

The lower, second face end 9 of the armature bolt is acted upon via an actuating force 22 (F_{MAGN}), which is equivalent to the force that must be generated by the magnetic circuit.

In the process of joining the magnet armature 1, that is, in joining the armature plate 2 along the circumferential surface of the armature bolt 7, a relative position 21 is established between these components of the magnet armature 1. The armature bolt 7 of the magnet armature 1 is received in a through opening 11 of a magnet core 10. The through opening 11 of the magnet core 10 has a play 12, so that a guided vertical motion of the magnet armature 1 is possible relative to the magnet core 10. The side of the through opening 11 oriented toward the circumferential surface of the armature bolt 7 of the magnet armature 1 is identified by reference numeral 13. The magnet core 10, which receives a magnet coil 17, includes a first face end 14 and a second face end 15. Within the magnet core 10, a recess 16 is embodied that receives the annularly configured magnet coil 17. The upper face end of the annular magnet coil, that is, the face end 18, ends flatly in the first face end 14 of the magnet core. When electric current is supplied to a magnetic circuit that has the magnet armature 1 and the magnet core 10 with the magnet coil 17 received in it, a magnetic flux identified by reference numeral 19 is established around the magnet coil 17 of the magnet core 10. The magnetic flux 19 established when current is supplied to the magnet coil 17 brings about a relative position of the armature plate 2 of the magnet armature 1 relative to the first face end 14 of the magnet core 10. As a result, when the magnetic circuit 19 is used for actuating a magnet armature assembly in a fuel injector, a vertically movable injection valve member can be actuated, or in other words moved up and down vertically, and as a result injection openings on the end of the fuel injector toward the combustion chamber can be closed and opened. The adjustment of the spacing h identified by reference numeral 20, of the remanent air gap between the armature plate 2 and the first face end 14 of the magnet core 10 with the magnet coil 17 let into it defines the accuracy with which the magnetic force to be brought to bear via the magnet armature assembly is exerted. The adjustment of the remanent air gap 20 (h) must be done with micrometer accuracy, since the force on the magnet armature 1 that results from the magnetic flux 19 varies sharply with the size h. This variation is virtually inversely proportional to the square of h. When a magnet armature assembly 1 is used as an actuating of an injection valve, it is necessary that an accurately defined force 22 be exerted. Accordingly, the remanent air gap 20 must be set with the requisite accuracy as well.

After the preassembly of the armature plate 2 on the armature bolt 7, in which the armature bolt 7 is fixed by means of the press fit 6 in the armature plate bore 5 of the armature plate 2, the relative position 21 is established between the armature plate 2 and the armature bolt 7. Instead of using graduated adjusting rings that remain in the injector body of the fuel injector in the assembly of the preassembled magnet armature 1 in the injector body, the proposed method of the invention provides that pressing of the preassembled magnet armature 1 in a pressing device is done retroactively.

In the reverse direction of action, that is, if a tensile force is exerted on the opposite face end of the armature bolt, conversely, the defined size 27 is set with extreme accuracy.

In the context of the retroactive pressing of the magnet armature 1 for the sake of fine calibration of the relative position 21 of the armature plate 2 at the circumference of the armature bolt 7, it is possible during the pressing operation to have recourse to precisely calibrated shims or spacers that can be placed replaceably in the pressing tool, which after the adjusting operation can be removed again. Before the preassembled magnet armature assembly is placed, these shims and spacers are placed in the pressing tool and determine the defined size 24 that is established, once the retroactive pressing operation has been performed between the second face end 9 of the armature bolt and the second face end 4 of the armature plate 2 of the magnet armature 1. The maintenance of the defined size 24 can be monitored for instance continuously by means of an optical measuring method using an optical measuring instrument associated with the pressing tool. Any measuring methods that are accurate to the micrometer range can be considered, such as inductive, capacitive, optical, or magnetic measuring methods.

In the retroactive pressing of the preassembled magnet armature 1 in a pressing device, the use of graduated compensation disks and graduated adjusting rings can be dispensed with in assembling a magnet armature assembly. Operations to be performed retroactively, such as trueing or metal-cutting postmachining (grinding operations), can be avoided when the adjusting method proposed according to the invention is used. The tolerances of the components of the magnet armature 1, that is, of the armature plate 2 and the armature bolt 7, can be made greater, which favorably affects the production of these components in terms of the machining time and the production costs. If the tolerances are broadened, then a plurality of shims or calibrated spacers should be used. However, the measurement of the first defined size 24 is preferably done during the adjusting operation, that is, the adjustment of the relative position 21 between the armature plate 2 and the armature bolt 7. Once the first defined size 24, which in the view in FIG. 1 is shown as the spacing between the second face end 9 of the armature bolt and the second face end 4 of the armature plate 2, is reached, the pressing is terminated at that instant.

In the performance of the retroactive pressing operation after the preassembly of the magnet armature 1 that includes the armature plate 2 and the armature bolt 7, the armature plate 2 can be placed in a pressing device 30. This is followed by the exertion of a pressing force 31 (F) on the armature bolt 7, penetrating the armature plate 2 at the armature plate bore 5, on one of its face ends 8 or 9. The pressing force of the pressing device acting on one of the face ends 8 or 9 of the armature bolt 7 brings about a relative motion of the armature bolt 7 to the armature plate bore 5 at the press fit 6 that is established in the course of the preassembly of the magnet armature 1. The pressing force 31 exerted on one of the face ends 8 or 9 of the armature bolt 7 by the pressing device 30 is maintained until such time as the first defined size 24 between the second face end 9 of the armature bolt and the second face end 4 of the armature plate 2 is set. In the view shown in FIG. 1, the first defined size 24 is the size to be set accurately.

In the view of FIG. 1, the magnetic force 22 (F_{MAGN}) engages the second face end 9 of the armature bolt. If the actuating force 22 (F_{MAGN}) engages the first face end 8 of the armature bolt 7, which is also one possible application, then the second defined size 27 would be the size to be set accurately.

It is also possible, in the retroactive pressing of the magnet armature 1 inside a pressing device, to fix the armature bolt 7 in the pressing device and to exert the pressing force on the armature plate 2 that is fixed on the armature bolt 7 at the press fit 6. In this way as well, the first defined size 24 shown in the drawing can be brought about; it characterizes the spacing between the second face end 4 of the armature plate 2 and the second face end 9 of the armature bolt of the magnet core 10, with the magnet coil 17 let into it.

Once the relative position 21 of the magnet armature 1, that is, the defined size 24 between the second face end 9 of the armature bolt and the second face end 4 of the armature plate 2, is reached, the magnet armature 1 is removed from the pressing device 30. The magnet armature 1 can be integrated with the magnet armature assembly without the use of compensation disks or graduated adjusting rings that were previously conventionally used in fuel injectors to adapt the remanent air gap 20. Because of the defined position of the second face end 15 of the magnet core 10 in the injector body and because of the defined installed position of the magnet armature 1 in the injector body, upon the mounting of a magnet armature 1 pressed by the method proposed according to the invention in the injector body, the spacing h, or remanent air gap 20, is established in the mounting process without requiring the use of graduated compensation disks or graduated adjusting rings that remain in the injector body. The first defined size, which is set to extreme accuracy by the method proposed, is unique to precisely one part, which depending on its production has defined geometric tolerances. Once the first defined size 24 is set precisely, the injector body and the magnet armature 1 are paired and should be used only together as a matched set. For the next injector body, which may have different production deviations, another first defined size 24 will be established, and thus the next magnet armature assembly will be pressed with a somewhat different first defined size 24 that precisely fits a further injector body. Thus a further injector body and a further magnet armature 1 are paired, or in other words can be used only together.

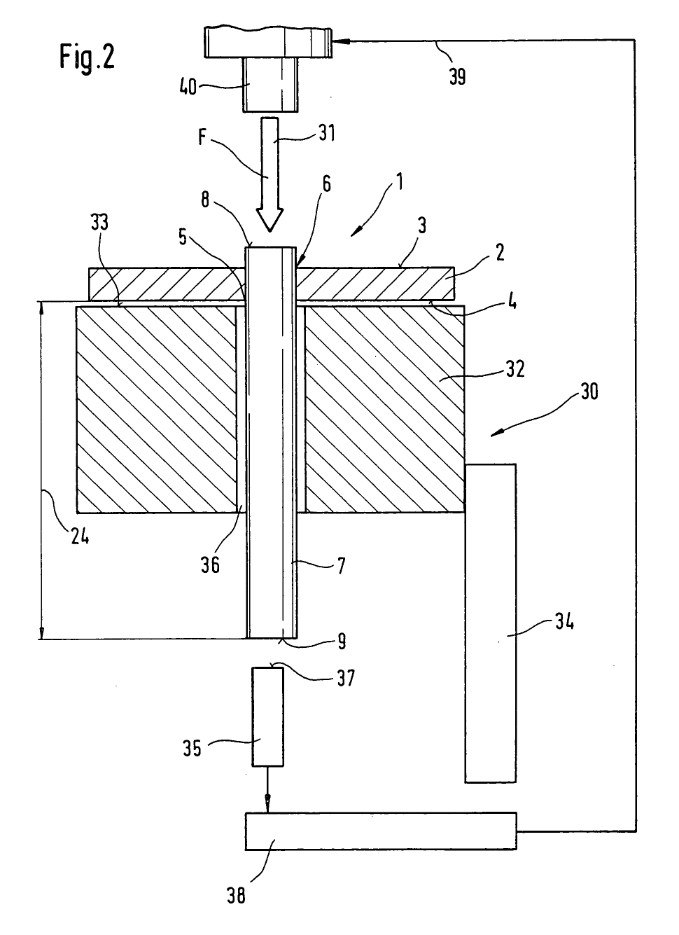

From the view in FIG. 2, a pressing device can be seen which is identified by reference numeral 30. The pressing device generates a pressing force 31 (F), which in the view of FIG. 2 acts on the first face end 8 of the armature bolt 7. As a result, the armature plate 2 rests flush with its second face end 4 on a face end 33 of a receiving device 32 of the pressing device 30. The armature bolt 7, which is received in an armature plate bore 5 by means of a press fit 6, is acted upon by the pressing force 31 (F) exerted by the pressing device 30 until such time as it is ascertained, via a measuring feeler 35 located opposite the second face end 9 of the armature bolt 7, that the first defined size 24 has reached the set-point value. The set-point value for the first defined size 24 will have been ascertained in advance and depends on the individual component tolerances of the preassembled magnet armature assembly 1. The pressing device 30 generates a pressing force 31 (F), which at constant speed pushes the armature bolt 7 onward through the armature plate 2. The pressing force 31 (F) could equally well engage the second face end 9 of the armature bolt instead. In that possible application, the second defined size 27 shown in the view in FIG. 1 is then the size to be precisely set.

The foregoing relates to preferred exemplary embodiments of the invention, it being understood that other variants and embodiments thereof are possible within the spirit and scope of the invention, the latter being defined by the appended claims.

We claim:

1. A method for adjusting a spacing (20) within a magnetic circuit, in particular the spacing (20) between a magnet armature (1) and a magnet core (10), in which the magnet armature (1) has an armature plate (2) and an armature bolt (7) which are joined together in a relative position (21), the method comprising adjusting the relative position (21) between the armature plate (2) and the armature bolt (7) by a pressing operation, to a first defined size (24) or a second defined size (27), after the armature plate (2) and the armature bolt (7) are assemleted to form the magnet armature (1).

2. The method of claim 1, further comprising monitoring the first defined size (24), characterizing the relative position (21) by means of a travel measuring system during the pressing operation.

3. The method of claim 1, wherein the pressing operation for adjusting the relative position (21) is effected in a pressing tool, by means of calibrated spacers that can be placed in the tool.

4. The method of claim 1, wherein the pressing operation for adjusting the relative position (21) is effected in a pressing tool, by means of calibrated shims that can be placed in the tool.

5. The method of claims 3, wherein after the pressing operation of the assembled magnet armature (1), the calibrated spacers or the calibrated shims are removed from the magnet armature.

6. The method of claims 4, wherein after the pressing operation of the assembled magnet armature (1), the calibrated spacers or the calibrated shims are removed from the magnet armature.

7. The method of claim 1, further comprising resting the armature plate (2) on one face end (33) of a receiving device (32) during the pressing operation of the preassembled magnet armature assembly (1), and acting upon the armature bolt (7) on one of its face ends (8, 9) with a pressing force (31) (F).

8. The method of claim 1, wherein in the pressing operation of the preassembled magnet armature assembly (1), the armature bolt (7) is fixed, and the armature plate (2) is acted upon with a pressing force (31) (F).

9. The method of claim 7, wherein during the pressing operation on the preassembled magnet armature assembly (1), the armature bolt (7) is thrust at a constant speed through an armature plate bore (5) of the armature plate (2).

10. The method of claim 1, wherein during the pressing operation of the magnet armature (1), a press fit (6) of the armature plate (2) on the jacket face of the armature bolt (7) is varied in terms of the relative position (21) of the armature plate (2) on the circumferential face of the armature bolt (7).

11. The method of claim 1, wherein during the pressing operation, the second defined size (27), characterizing the relative position (21) between the armature bolt (7) and the armature plate (2), is monitored continuously by means of a measuring feeler (35).

12. The method of claim 11, wherein the pressing force (31) (F) is initiated at the first face end (8) of the armature bolt (7) for adjusting the second defined size (27).

13. The method of claim 1, wherein the pressing force (31) (F) is applied to the preassembled magnet armature assembly (1) until such time as either the first defined size (24) or the second defined size (27) is reached, and wherein the pressing operation is ended via the measuring feeler (35) and a travel measuring system (38) disposed downstream of it.
